(19) United States
(12) Patent Application Publication
(10) Pub. No.: US 2025/0118599 A1
(43) Pub. Date: Apr. 10, 2025

(54) Semiconductor Device and Method of Forming Embedded Trace Substrate with Barrier Layer to Inhibit Electromigration

(71) Applicant: JCET STATS ChipPAC Korea Limited, Incheon (KR)

(72) Inventors: SeungHyun Lee, Incheon (KR); HeeSoo Lee, Incheon (KR); YongMoo Shin, Incheon (KR)

(73) Assignee: JCET STATS ChipPAC Korea Limited, Incheon (KR)

(21) Appl. No.: 18/482,377

(22) Filed: Oct. 6, 2023

(51) Int. Cl. H01L 21/768; H01L 23/00; H01L 23/522; H01L 23/532

(52) U.S. Cl. CPC H01L 21/76871; H01L 21/76831; H01L 23/5226; H01L 23/53238; H01L 24/16; H01L 2224/16225; H01L 2924/1531

(57) ABSTRACT

A semiconductor device has an interconnect substrate with a first conductive layer and a first barrier layer formed over a first portion of the first conductive layer and a second barrier layer formed over a second portion of the first conductive layer. The first barrier layer and second barrier layer substantially surround or enclose the first conductive layer. The first barrier layer is a conductive material, and the second barrier layer includes a non-conductive material. The interconnect structure further has a second conductive layer coupled to the first conductive layer with an insulating layer formed between the first conductive layer and second conductive layer. A third barrier layer is formed over a first portion of the second conductive layer, and a fourth barrier layer is formed over a second portion of the second conductive layer. An electrical component is disposed over the interconnect substrate.

### FIELD OF THE INVENTION

The present invention relates in general to semiconductor devices and, more particularly, to a semiconductor device and method of forming an embedded trace substrate with a barrier layer to inhibit electromigration from conductive layers.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

A semiconductor wafer typically contains a plurality of semiconductor die separated by a saw street. The semiconductor wafer is singulated into a plurality of individual semiconductor die. A semiconductor package may contain a semiconductor die mounted to an interconnect substrate. The electrical interconnect structures within the interconnect substrate can be subject to electromigration, particularly for small geometries, fine pitch, and minimal line/space. Electromigration is the transport of material caused by the gradual movement of ions in a conductive layer due to the momentum transfer between conducting electrons and diffusing metal atoms. Electromigration causes defects, such as the formation of voids and hillocks, which can cause reliability issues such as opens or shorts. The formation of defects is associated with the evolution of strain and stress within the conductive materials. Electromigration can decrease reliability and yield and increase defects and manufacturing costs.

### BRIEF DESCRIPTION OF THE DRAWINGS

FIGS. 1a-1c illustrate a semiconductor wafer with a plurality of semiconductor die separated by a saw street;

FIGS. 2a-2r illustrate a process of forming an interconnect substrate with a barrier layer formed around a conductive layer to inhibit electromigration;

FIGS. 3a-3k illustrate another process of forming an interconnect substrate with a barrier layer formed around a conductive layer to inhibit electromigration; and

FIG. 4 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

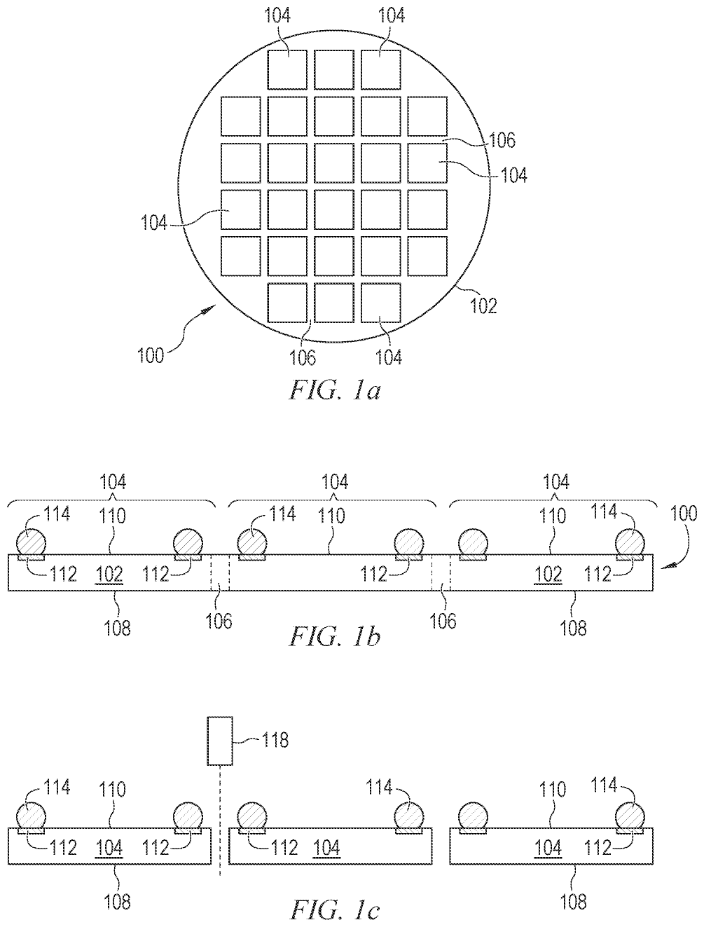

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 119 into individual semiconductor die 104. The individual semiconductor die 104 can be inspected and electrically tested for identification of known good die or unit (KGD/KGU) post singulation.

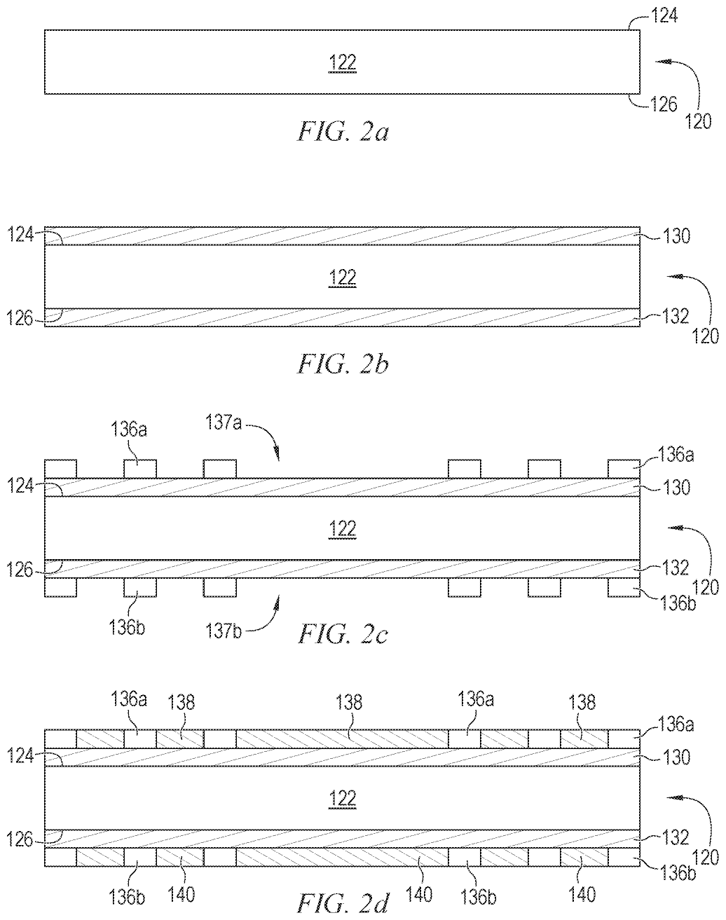

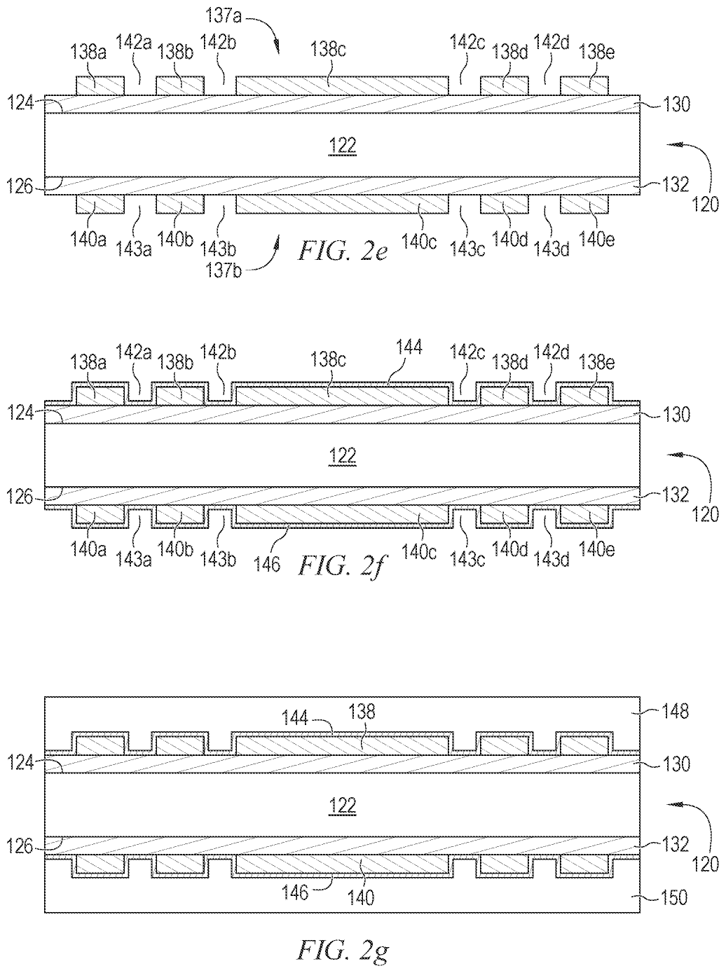

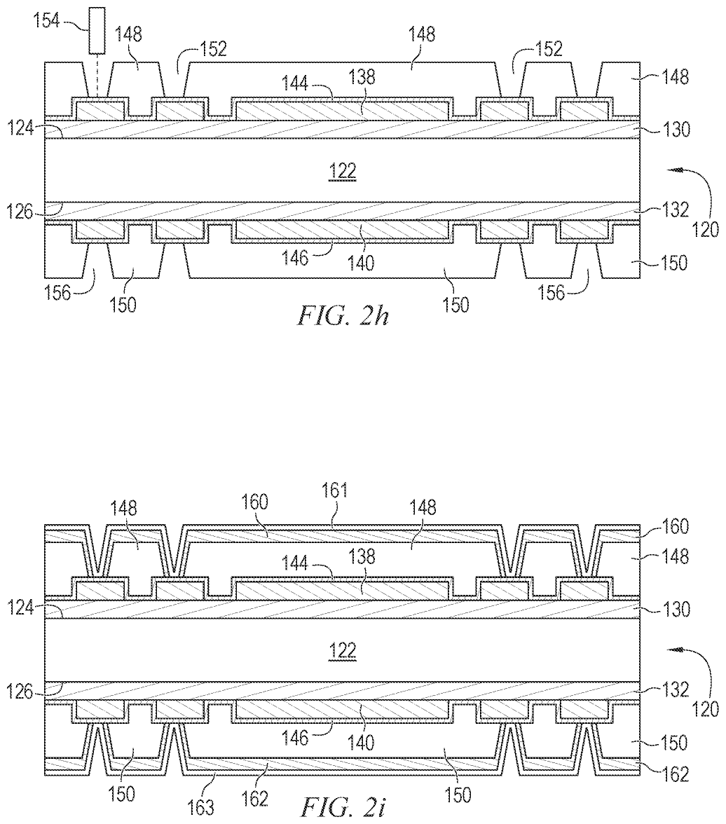

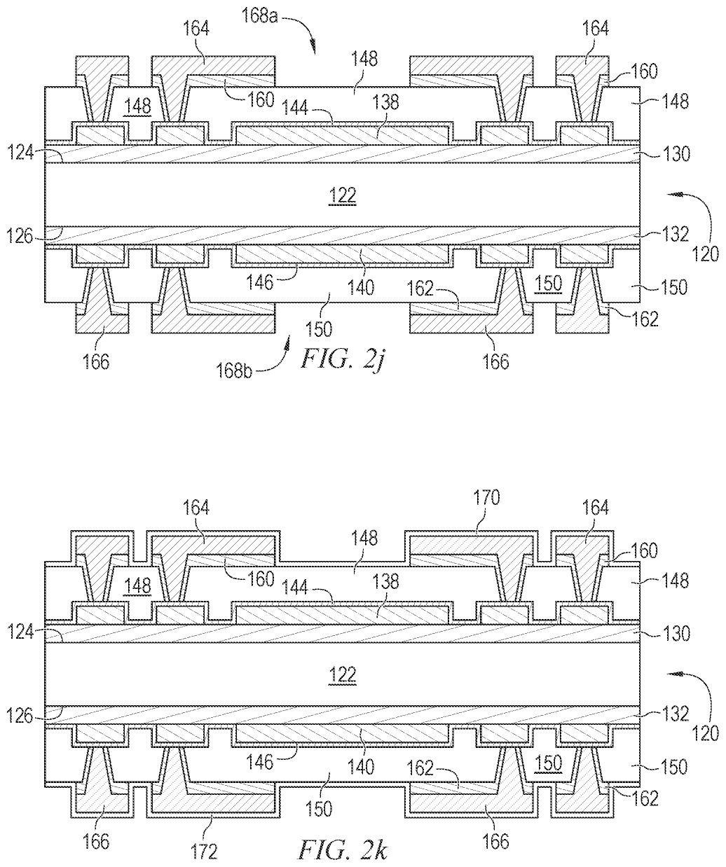

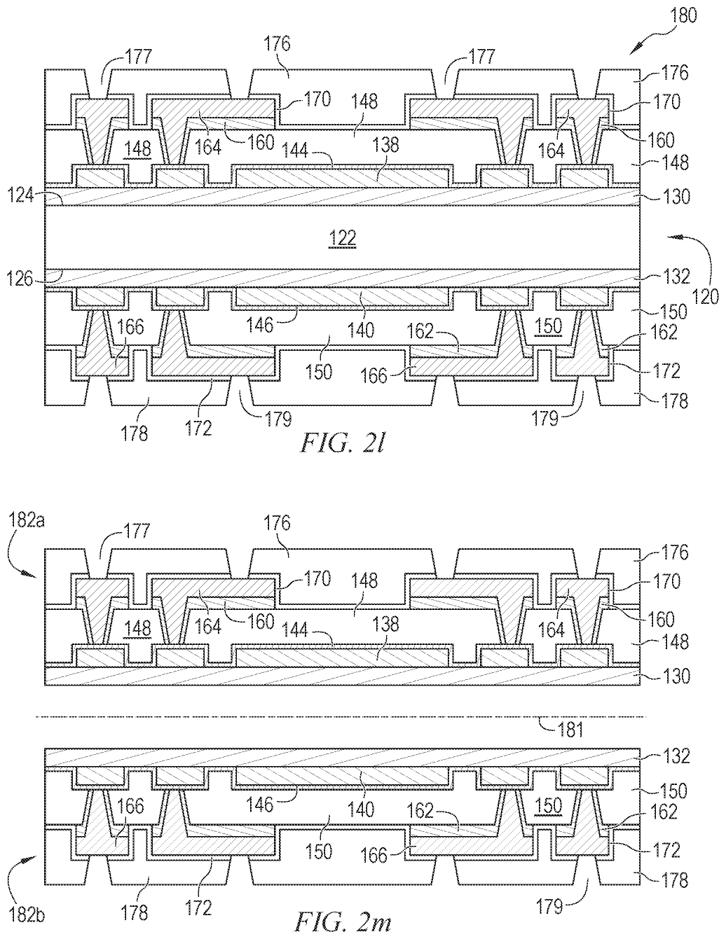

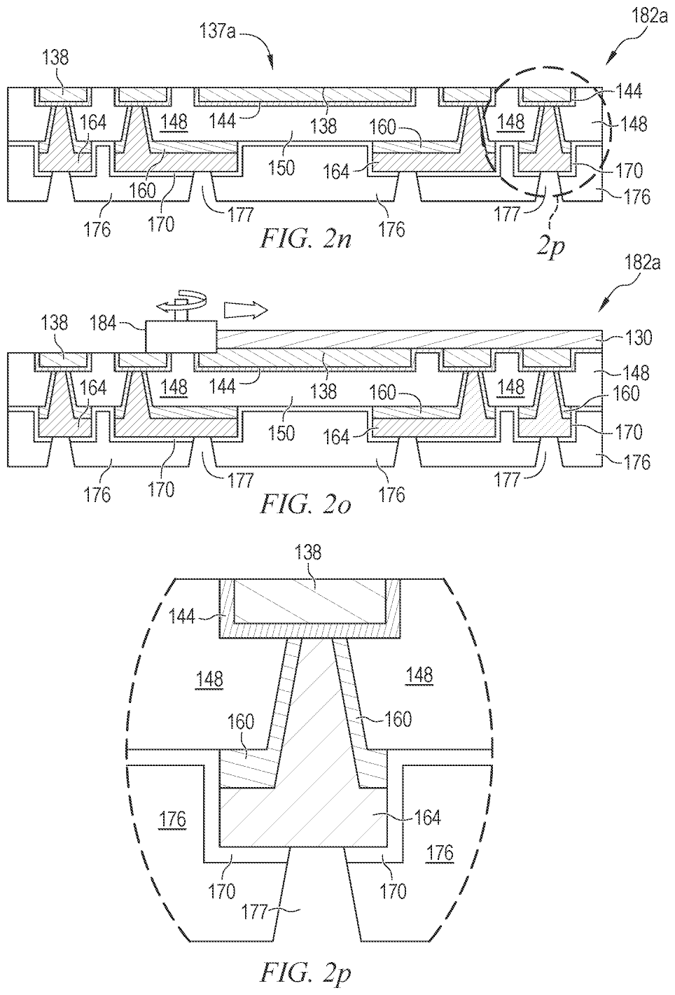

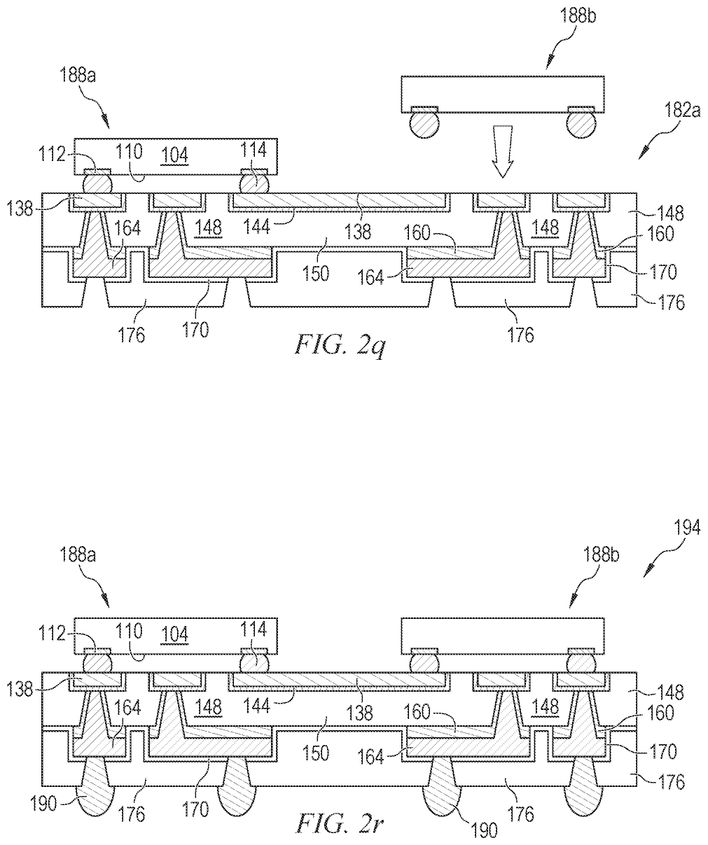

FIGS. 2a-2r illustrate a process of forming a double-sided embedded trace substrate (ETS) with a barrier layer formed around a conductive layer to inhibit electromigration. FIG. 2a shows a core substrate 120 made with base material 122 as a multi-layer flexible laminate, ceramic, copper clad laminate (CCL), glass, or epoxy molding compound. Base material 122 can contain one or more layers of SiO2, Si3N4, SiON, Ta2O5, Al2O3, solder resist, polyimide, BCB, PBO, and other material having similar insulating and structural properties. Core substrate 120 may include one or more laminated layers of polytetra-fluoroethylene (PTFE) pre-impregnated (prepreg), FR-4, FR-1, CEM-1, or CEM-3 with a combination of phenolic cotton paper, epoxy, resin, woven glass, matte glass, polyester, and other reinforcement fibers or fabrics. In another embodiment, core substrate 120 can also be any suitable laminate interposer, PCB, wafer-form, strip interposer, leadframe, or other type of substrate. Core substrate 120 has a thickness of 150.0 micrometers (μm) and includes first major surface 124 and second major surface 126 opposite surface 124.

In FIG. 2b, electrically conductive layer 130 is formed on surface 124, and electrically conductive layer 132 is formed on surface 126. Conductive layers 130 and 132 can be formed using PVD, CVD, electrolytic plating, electroless plating process, or other suitable metal deposition process. Conductive layers 130 and 132 can be one or more layers of Al, Cu, Sn, Ni, Au, Ag, or other suitable electrically conductive material. The combination of core substrate 120 and conductive layers 130 and 132 constitute a CCL substrate.

In FIG. 2c, a photoresist layer 136 is formed over conductive layers 130 and 132. Photoresist layer 136a is patterned and etched to form circuit layout or pattern 137a over conductive layer 130, and photoresist layer 136b is patterned and etched to form circuit layout or pattern 137b over conductive layer 132. Alternatively, circuit patterns 137a and 137b can be formed by laser direct ablation (LDA).

In FIG. 2d, electrically conductive layer 138 is formed in circuit pattern 137a defined by photoresist layer 136a, and electrically conductive layer 140 is formed in circuit pattern 137b defined by photoresist layer 136b. Conductive layers 138 and 140 can be formed using PVD, CVD, electrolytic plating, electroless plating process, or other suitable metal deposition process. Conductive layers 138 and 140 can be one or more layers of Al, Cu, Sn, Ni, Au, Ag, or other suitable electrically conductive material.

In FIG. 2e, photoresist layers 136a and 136b are removed leaving conductive layers 138 and 140 in circuit patterns 137a and 137b, respectively. In particular, conductive layer segment 138a has separation 142a from conductive layer segment 138b, and conductive layer segment 138b has separation 142b from conductive layer segment 138c. Conductive layer segment 138c has separation 142c from conductive layer segment 138d, and conductive layer segment 138d has separation 142d from conductive layer segment 138e. Likewise, conductive layer segment 140a has separation 143a from conductive layer segment 140b, and conductive layer segment 140b has separation 143b from conductive layer segment 140c. Conductive layer segment 140c has separation 143c from conductive layer segment 140d, and conductive layer segment 140d has separation 143d from conductive layer segment 140e. Conductive layer segments 138a-138b with separations 142a-142d define circuit pattern 137a. Conductive layer segments 140a-140b with separations 143a-143d define circuit pattern 137b.

In FIG. 2f, protection or barrier layer 144 is conformally applied over conductive layers 130 and 138, including in-between separations 142a-142d. Protection or barrier layer 146 is conformally applied over conductive layers 132 and 140, including in-between separations 143a-143d. Barrier layers 144 and 146 can be formed using PVD, CVD, electrolytic plating, electroless plating process, or other suitable metal deposition process. Barrier layers 144 and 146 can be tantalum, tantalum nitride, tantalum silicon nitride, tungsten, tungsten nitride, tungsten silicon nitride, titanium, titanium nitride, titanium silicon nitride, or cobalt (Co). In another embodiment, barrier layers 144 and 146 can be Co, iridium (Ir), or ruthenium (Ru), or alloy materials thereof with tungsten (W), boron (B), phosphorus (P), molybdenum (Mo), or rhenium (Re).

In FIG. 2g, an insulating layer 148 is formed over barrier layer 144, and an insulating layer 150 is formed over barrier layer 146. Insulating layers 148 and 150 can be formed using PVD, CVD, printing, lamination, spin coating, spray coating, sintering, or thermal oxidation. Insulating layers 148 and 150 contain one or more layers of silicon dioxide (SiO2), silicon nitride (Si3N4), silicon oxynitride (SiON), tantalum pentoxide (Ta2O5), aluminum oxide (Al2O3), titanium dioxide (TiO2), solder resist, polyimide, benzocyclobutene (BCB), polybenzoxazoles (PBO), and other material having similar insulating and structural properties. In one embodiment, insulating layers 148 and 150 can be a dielectric material, such as Ajinomoto build-up film (ABF) or polytetrafluoroethylene (PTFE) pre-impregnated (prepreg or PPG) laminated over circuit patterns 137a and 137b.

In FIG. 2h, a portion of insulating layers 148 and 150 is removed by an etching process or LDA using laser 154 to form openings or vias 152 and 156, respectively. Openings 152 extend to barrier layer 144 and openings 156 extend to barrier layer 146.

In FIG. 2i, protection or barrier layer 160 is conformally applied over insulating layer 148 and into vias 152 over barrier layer 144. Likewise, protection or barrier layer 162 is conformally applied over insulating layer 150 and into vias 156 over barrier layer 146. Barrier layers 160 and 162 can be formed using PVD, CVD, electrolytic plating, electroless plating process, or other suitable metal deposition process. Barrier layers 160 and 162 can be tantalum, tantalum nitride, tantalum silicon nitride, tungsten, tungsten nitride, tungsten silicon nitride, titanium, titanium nitride, titanium silicon nitride, or Co. In another embodiment, barrier layers 160 and 162 can be Co, Ir, or Ru, or alloy materials thereof with W, B, P, Mo, or Re. An optional seed layer 161 can be conformally applied over barrier layer 160, and an optional seed layer 163 can be conformally applied over barrier layer 162.

In FIG. 2j, an electrically conductive layer 164 is formed over barrier layer 160 and into vias 152 extending to barrier layer 144. Likewise, an electrically conductive layer 166 is formed over barrier layer 162 and into vias 156 extending to barrier layer 146. Conductive layers 164 and 166 can be formed using PVD, CVD, electrolytic plating, electroless plating process, or other suitable metal deposition process. Conductive layers 164 and 166 can be one or more layers of Al, Cu, Sn, Ni, Au, Ag, or other suitable electrically conductive material. Conductive layers 164 and 166, as well as barrier layers 160 and 162, are patterned and etched according to circuit pattern or layout 168a and 168b of the interconnect substrate, i.e., with conductive traces routed to provide electrical function. Alternatively, circuit layout 168a-168b can be formed by LDA. Portions of conducive layers 164 and 166 are electrically common or electrically isolated depending on the design and function of later added electrical components. There can be multiple conductive layers like 164 and 166 separated by multiple insulating layers like 148 and 150.

In FIG. 2k, protection or barrier layer 170 is conformally applied over conductive layer 164 and insulating layer 148. Likewise, protection or barrier layer 172 is conformally applied over conductive layer 166 and insulating layer 150. Barrier layers 170 and 172 can be formed using PVD, CVD, printing, lamination, spin coating, spray coating, sintering, or thermal oxidation. Barrier layers 170 and 172 can be SiO2, Si3N4, SiON, Ta2O5, Al2O3, TiO2, solder resist, polyimide, BCB, PBO, and other material having similar insulating and/or non-conductive properties.

In FIG. 2l, an insulating layer 176 is formed over barrier layer 170 and insulating layer 148, and insulating layer 178 is formed over barrier layer 172 and insulating layer 150. Insulating layers 176 and 178 can be formed using PVD, CVD, printing, lamination, spin coating, spray coating, sintering, or thermal oxidation. Insulating layers 176 and 178 contain one or more layers of SiO2, Si3N4, SiON, Ta2O5, Al2O3, TiO2, solder resist, polyimide, BCB, PBO, and other material having similar insulating and structural properties. A portion of insulating layers 176 and 178 is removed by an etching process or LDA to form openings or vias 177 and 179, respectively. Openings 177 extend to conductive layer 164 and openings 179 extend to conductive layer 166.

The assembly in FIG. 2l is a double-sided interconnect substrate 180 as an ETS and further including internal barrier layers 144, 146, 160, 162, 170, and 172 to inhibit electromigration. In FIG. 2m, double-sided interconnect substrate 180 is singulated along line 181 by removing core substrate 120, leaving interconnect substrate 182a and interconnect substrate 182b.

In FIG. 2n, conductive layer 130 and a portion of barrier layer 144 on interconnect substrate or ETS 182a is removed by an etching process, e.g., acid etching, to isolate circuit pattern 137a. A similar etching operation occurs to remove conductive layer 132 and a portion of barrier layer 146 and isolate circuit pattern 137b on interconnect substrate or ETS 182b. Alternatively, interconnect substrate or ETS 182a undergoes a grinding operation using grinder 184 to remove conductive layer 130 and a portion of barrier layer 144 to isolate circuit pattern 137a, as shown in FIG. 20. A similar grinding operation occurs for interconnect substrate or ETS 182b to remove conductive layer 132 and a portion of barrier layer 146 to isolate circuit pattern 137b. Conductive layer 138 with circuit pattern 137a is exposed from interconnect substrate or ETS 182a. Conductive layers 138 and 164 primarily provide electrical communication or signal propagation through interconnect substrate or ETS 182a.

FIG. 2p shows further detail from FIG. 2n with barrier layer 144 around conductive layer 138 and barrier layer 160 formed over a first portion of conductive layer 164 and barrier layer 170 formed over a second portion of conductive layer 164. Electromigration is the transport of material caused by the gradual movement of ions in a conductive layer due to the momentum transfer between conducting electrons and diffusing metal atoms. In interconnect substrate or ETS 182a, conductive layers 138 and 164 are subject to electromigration. As the structure and size of conductive layers in semiconductor devices decrease, the practical significance of electromigration becomes more apparent. Electromigration causes defects, such as the formation of voids and hillocks, which can cause reliability problems such as opens or shorts. The formation of defects is associated with the evolution of strain and stress within the conductive materials. Electromigration between conductive layers 138 and 164 and portions thereof can adversely affect electrical communications and signal propagation through interconnect substrate or ETS 182a. Barrier layers 144, 160, and 170 reduce or inhibit electromigration with respect to conductive layers 138 and 164 in interconnect substrate or ETS 182a. For example, barrier layers 160 and 170 substantially surround or enclose conductive layer 164, aside from the direct conductive path, to reduce or inhibit electromigration. Barrier layers 144, 160, and 170 increase reliability for interconnect substrate or ETS 182a by reducing or inhibiting electromigration between internal conductive layers 140 and 166. In a similar manner, barrier layers 146, 162, and 172 inhibit electromigration with respect to conductive layers 140 and 166 to increase reliability for interconnect substrate or ETS 182b.

In FIG. 2q, electrical components 188a and 188b are disposed over interconnect substrate 182a and electrically and mechanically connected to conductive layer 138. For example, electrical component 188a-188b can be similar to, or made similar to, semiconductor die 104 from FIG. 1c with bumps 114 oriented toward conductive layer 138. Electrical components 188a-188b can be other semiconductor die, semiconductor packages, surface mount devices, RF components, discrete electrical devices, or integrated passive devices (IPD).

Electrical component 188a-188b are positioned over interconnect substrate or ETS 182a using a pick and place operation. Bumps 114 are reflowed to make mechanical and electrical connection to conductive layer 138. FIG. 2r shows electrical components 188a-188b electrically and mechanically connected to conductive layer 138 of interconnect substrate or ETS 182a.

An electrically conductive bump material is deposited into vias 177 over conductive layer 164 on interconnect substrate or ETS 182a using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 164 using a suitable attachment or bonding process. In one embodiment, the bump material is reflowed by heating the material above its melting point to form balls or bumps 190. In one embodiment, bump 190 is formed over a UBM having a wetting layer, barrier layer, and adhesive layer. Bump 190 can also be compression bonded or thermocompression bonded to conductive layer 164. Bump 190 represents one type of interconnect structure that can be formed over conductive layer 164. The interconnect structure can also use bond wires, conductive paste, stud bump, micro bump, or other electrical interconnect. The combination of interconnect substrate or ETS 182a and electrical components 188a-188b constitutes semiconductor package 194.

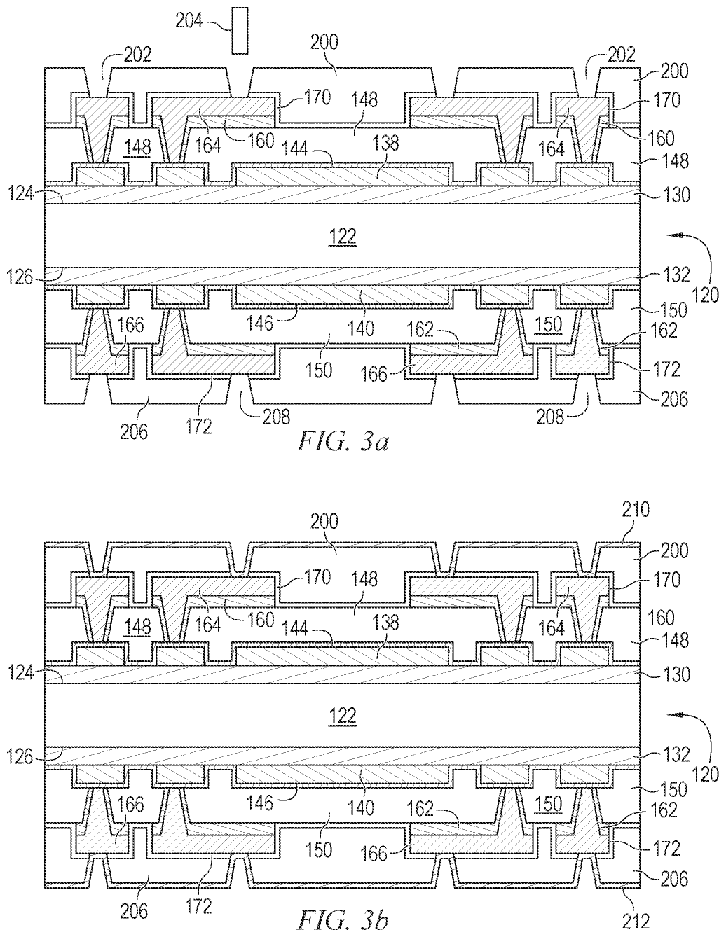

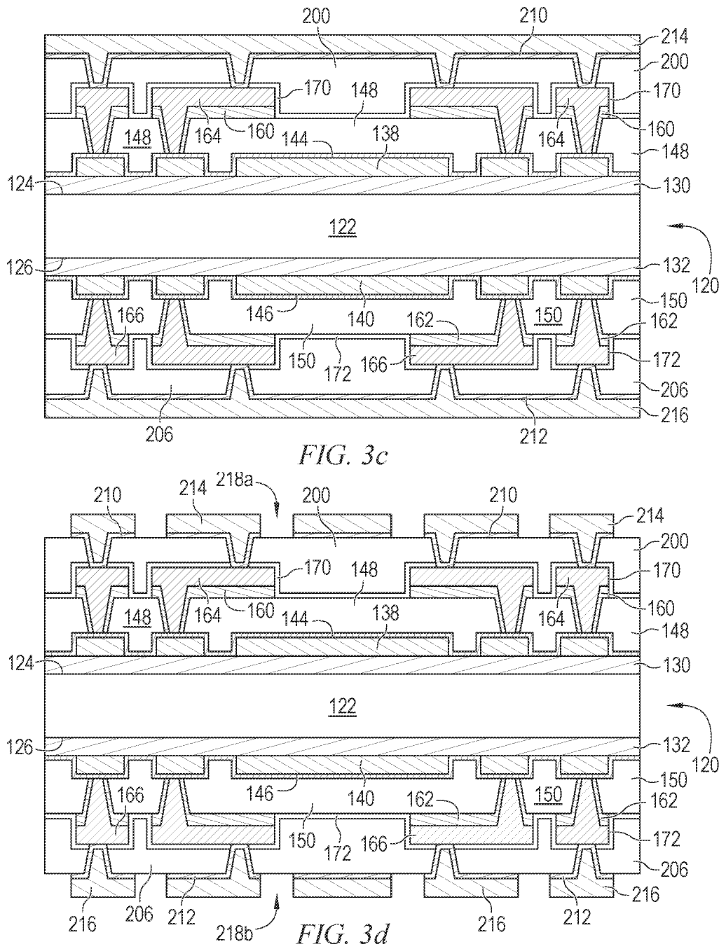

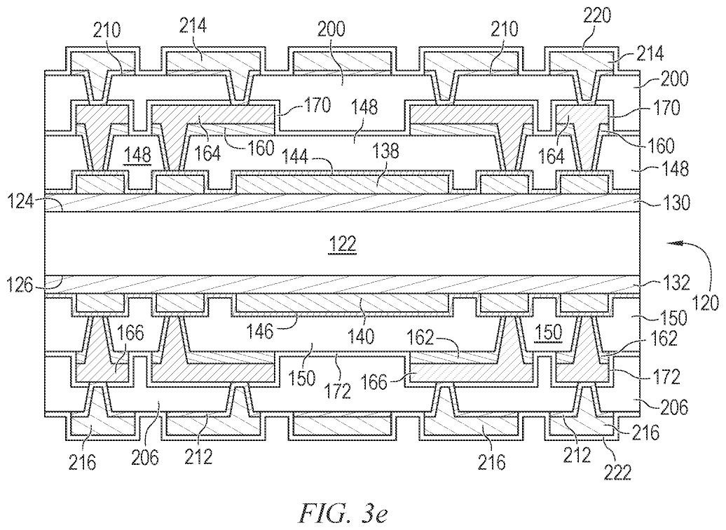

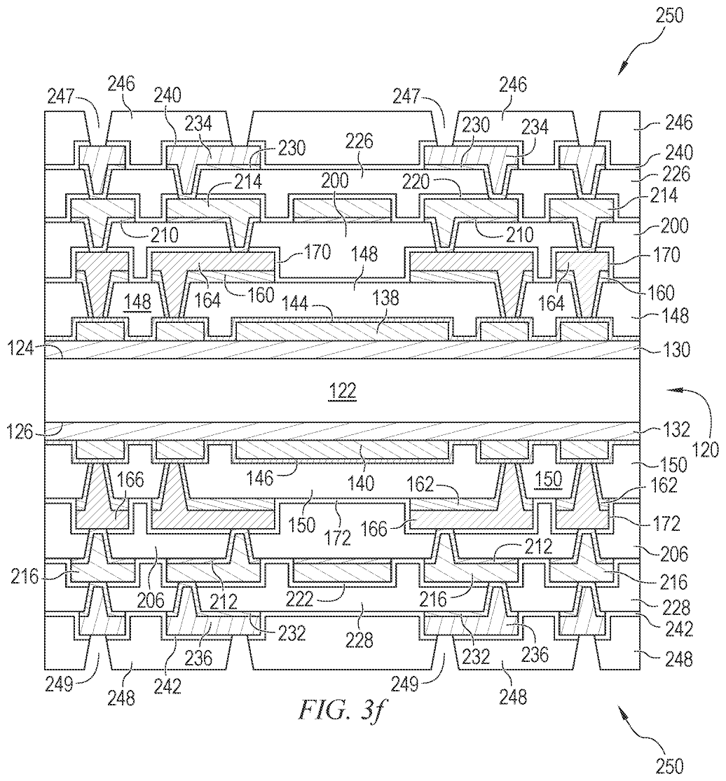

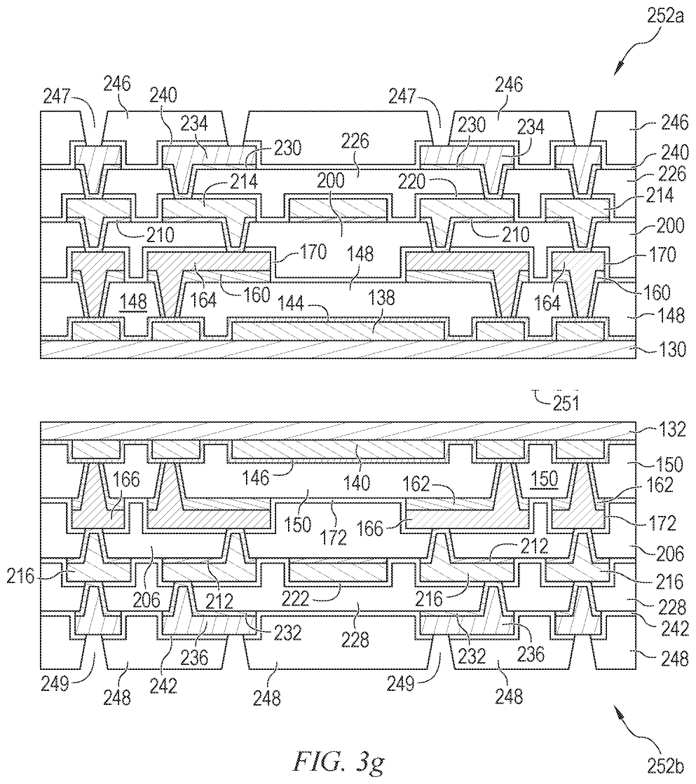

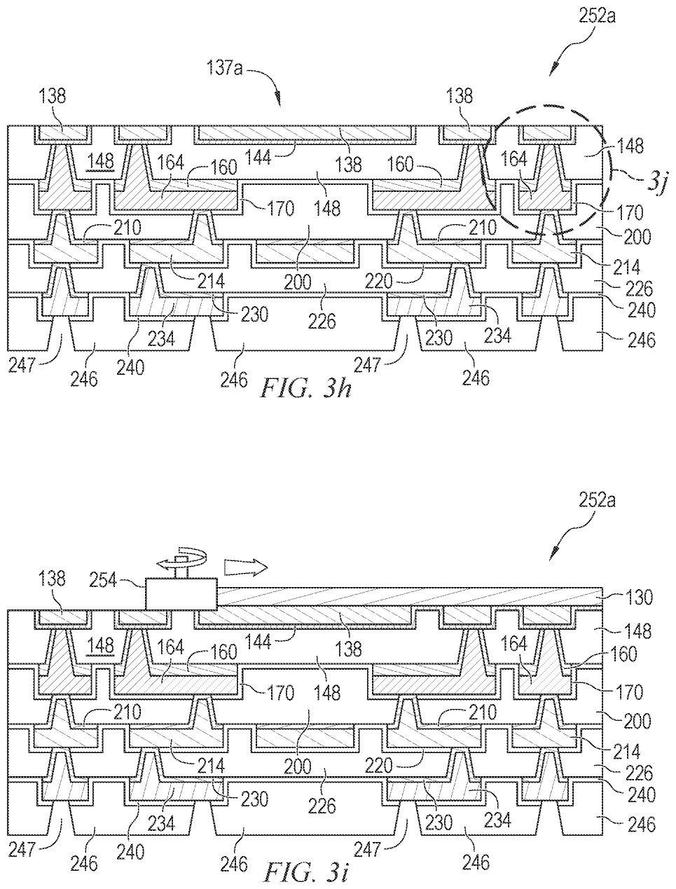

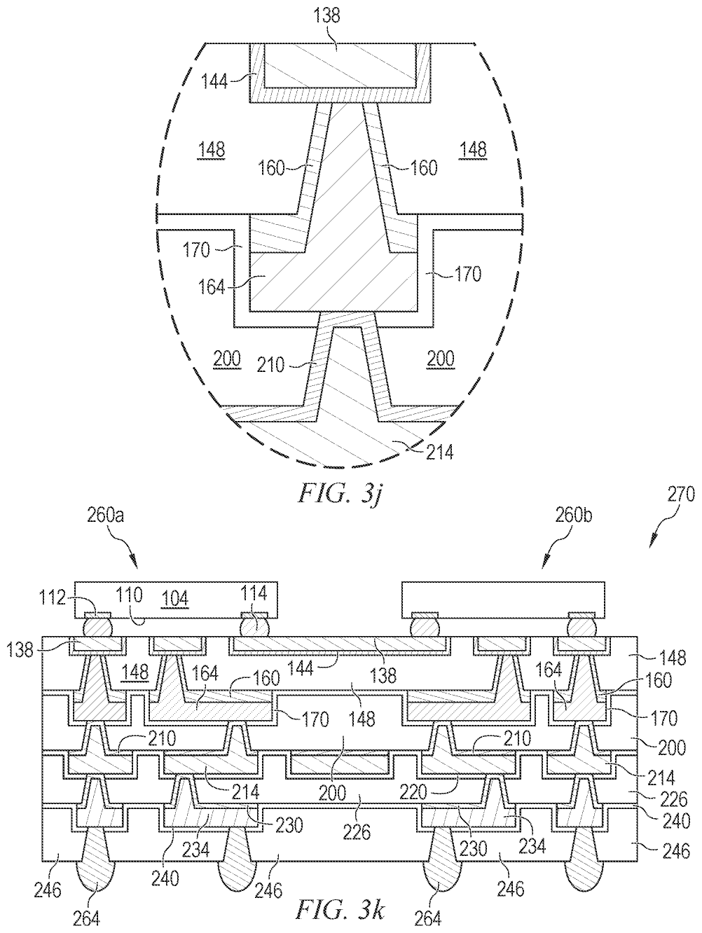

In another embodiment, continuing from FIG. 2k, an insulating layer 200 is formed over barrier layer 170, and insulating layer 206 is formed over barrier layer 172, as shown in FIG. 3a. Elements that have a similar function are assigned the same reference number. Insulating layers 200 and 206 can be formed using PVD, CVD, printing, lamination, spin coating, spray coating, sintering, or thermal oxidation. Insulating layers 200 and 206 contain one or more layers of SiO₂, Si3N4, SiON, Ta2O5, Al2O3, TiO2, solder resist, polyimide, BCB, PBO, and other material having similar insulating and structural properties. A portion of insulating layers 200 and 206 is removed by an etching process or LDA to form openings or vias 202 and 208, respectively. Openings 202 extend to conductive layer 164 and openings 208 extend to conductive layer 166.

In FIG. 3b, protection or barrier layer 210 is conformally applied over insulating layer 200 and into vias 202 over conductive layer 164. Likewise, protection or barrier layer 212 is conformally applied over insulating layer 206 and into vias 208 over conductive layer 166. Barrier layers 210 and 212 can be formed using PVD, CVD, electrolytic plating, electroless plating process, or other suitable metal deposition process. Barrier layers 210 and 212 can be tantalum, tantalum nitride, tantalum silicon nitride, tungsten, tungsten nitride, tungsten silicon nitride, titanium, titanium nitride, titanium silicon nitride, or Co. In another embodiment, barrier layers 210 and 212 can be Co, Ir, or Ru, or alloy materials thereof with W, B, P, Mo, or Re.

In FIG. 3c, an electrically conductive layer 214 is formed over barrier layer 210 and into vias 202. Likewise, an electrically conductive layer 216 is formed over barrier layer 212 and into vias 156. Conductive layers 214 and 216 can be formed using PVD, CVD, electrolytic plating, electroless plating process, or other suitable metal deposition process. Conductive layers 214 and 216 can be one or more layers of Al, Cu, Sn, Ni, Au, Ag, or other suitable electrically conductive material.

In FIG. 3d, conductive layers 214 and 216, as well as barrier layers 210 and 212, are patterned and etched according to circuit pattern or layout 218a and 218b of the interconnect substrate, i.e., with conductive traces routed to provide electrical function. Alternatively, circuit layout 218a and 218b can be formed by LDA. Portions of conducive layers 214 and 216 are electrically common or electrically isolated depending on the design and function of later added electrical components. There can be multiple conductive layers like 214 and 216 separated by multiple insulating layers like 200 and 206.

In FIG. 3e, protection or barrier layer 220 is conformally applied over conductive layer 214 and insulating layer 200. Likewise, protection or barrier layer 222 is conformally applied over conductive layer 216 and insulating layer 206. Barrier layers 220 and 222 can be formed using PVD, CVD, printing, lamination, spin coating, spray coating, sintering, or thermal oxidation. Barrier layers 220 and 222 can be SiO2, Si3N4, SiON, Ta2O5, Al2O3, TiO2, solder resist, polyimide, BCB, PBO, and other material having similar insulating and non-conductive properties.

In FIG. 3f, an insulating layer 226 is formed over barrier layer 220, and insulating layer 228 is formed over barrier layer 222. Insulating layers 226 and 228 can be formed using PVD, CVD, printing, lamination, spin coating, spray coating, sintering, or thermal oxidation. Insulating layers 226 and 228 contain one or more layers of SiO2, Si3N4, SiON, Ta2O5, Al2O3, TiO2, solder resist, polyimide, BCB, PBO, and other material having similar insulating and structural properties. A portion of insulating layers 226 and 228 is removed by an etching process or LDA to form openings or vias extending to conductive layers 214 and 216.

A protection or barrier layer 230 is conformally applied over insulating layer 226 and into the vias over conductive layer 214, similar to FIG. 2i. Likewise, protection or barrier layer 232 is conformally applied over insulating layer 228 and into the vias over conductive layer 216. Barrier layers 230 and 232 can be formed using PVD, CVD, electrolytic plating, electroless plating process, or other suitable metal deposition process. Barrier layers 230 and 232 can be tantalum, tantalum nitride, tantalum silicon nitride, tungsten, tungsten nitride, tungsten silicon nitride, titanium, titanium nitride, titanium silicon nitride, or Co. In another embodiment, barrier layers 230 and 232 can be Co, Ir, or Ru, or alloy materials thereof with W, B, P, Mo, or Re.

An electrically conductive layer 234 is formed over barrier layer 230, similar to FIG. 2j. Likewise, an electrically conductive layer 236 is formed over barrier layer 232. Conductive layers 234 and 236 can be formed using PVD, CVD, electrolytic plating, electroless plating process, or other suitable metal deposition process. Conductive layers 234 and 236 can be one or more layers of Al, Cu, Sn, Ni, Au, Ag, or other suitable electrically conductive material.

Conductive layers 234 and 236, as well as barrier layers 230 and 232, are patterned and etched according to the circuit pattern or layout of the interconnect substrate, i.e., with conductive traces routed to provide electrical function, similar to FIG. 2j. Alternatively, the circuit layout can be formed by LDA. Portions of conducive layers 234 and 236 are electrically common or electrically isolated depending on the design and function of later added electrical components. There can be multiple conductive layers like 234 and 236 separated by multiple insulating layers like 226 and 228.

A protection or barrier layer 240 is conformally applied over conductive layer 234 and insulating layer 226, similar to FIG. 2k. Likewise, protection or barrier layer 242 is conformally applied over conductive layer 236 and insulating layer 228. Barrier layers 240 and 242 can be formed using PVD, CVD, printing, lamination, spin coating, spray coating, sintering, or thermal oxidation. Barrier layers 240 and 242 can be SiO2, Si3N4, SiON, Ta2O5, Al2O3, TiO2, solder resist, polyimide, BCB, PBO, and other material having similar insulating and non-conductive properties.

An insulating layer 246 is formed over barrier layer 240, and insulating layer 248 is formed over barrier layer 242, similar to FIG. 2l. Insulating layers 246 and 248 can be formed using PVD, CVD, printing, lamination, spin coating, spray coating, sintering, or thermal oxidation. Insulating layers 246 and 248 contain one or more layers of SiO2, Si3N4, SiON, Ta2O5, Al2O3, TiO2, solder resist, polyimide, BCB, PBO, and other material having similar insulating and structural properties. A portion of insulating layers 246 and 248 is removed by an etching process or LDA to form openings or vias 247 and 249, respectively. Openings 247 extend to conductive layer 234 and openings 249 extend to conductive layer 236.

The assembly in FIG. 3f is a double-sided interconnect substrate 250 as an ETS and further includes internal barrier layers 144, 146, 160, 162, 170, 172, 210, 212, 220, 222, 230, 232, 240, and 242 to inhibit electromigration. In FIG. 3g, double-sided interconnect substrate 230 is singulated along line 251 by removing core substrate 120, leaving interconnect substrate 252a and interconnect substrate 252b.

In FIG. 3h, conductive layer 130 and a portion of barrier layer 144 on interconnect substrate or ETS 252a is removed by an etching process, e.g., acid etching, to isolate circuit pattern 137a. A similar etching operation occurs to remove conductive layer 132 and a portion of barrier layer 146 and isolate circuit pattern 137b on interconnect substrate or ETS 252b. Alternatively, interconnect substrate or ETS 252a undergoes a grinding operation using grinder 254 to remove conductive layer 130 and a portion of barrier layer 144 to isolate circuit pattern 137a, as shown in FIG. 3l. A similar grinding operation occurs for interconnect substrate or ETS 252b to remove conductive layer 132 and a portion of barrier layer 146 to isolate circuit pattern 137b. Conductive layer 138 with circuit pattern 137a is exposed from interconnect substrate or ETS 252a. Conductive layers 138, 164, 214, and 234 primarily provide electrical communication or signal propagation through interconnect substrate or ETS 252a.

FIG. 3j shows further detail from FIG. 3h with barrier layer 144 around conductive layer 138 and barrier layer 160 formed over a first portion of conductive layer 164 and barrier layer 170 formed over a second portion of conductive layer 164. In interconnect substrate or ETS 252a, conductive layers 138, 164, 214, and 234 are subject to electromigration. As the structure and size of conductive layers in semiconductor devices decrease, the practical significance of electromigration becomes more apparent. Electromigration causes defects, such as the formation of voids and hillocks, which can cause reliability problems such as opens or shorts. The formation of defects is associated with the evolution of strain and stress within the conductive materials. Electromigration between conductive layers 138, 164, 214, and 234 and portions thereof can adversely affect electrical communications and signal propagation through interconnect substrate or ETS 182a. Barrier layers 144, 160, 170, 210, 220, 230, and 240 reduce or inhibit electromigration with respect to conductive layers 138, 164, 214, and 234 in interconnect substrate or ETS 252a. For example, barrier layers 160 and 170 substantially surround or enclose conductive layer 164, aside from the direct conductive path, to reduce or inhibit electromigration. Likewise, barrier layers 210 and 220 substantially surround or enclose conductive layer 214, aside from the direct conductive path, to reduce or inhibit electromigration. Barrier layers 230 and 240 substantially surround or enclose conductive layer 234, aside from the direct conductive path, to reduce or inhibit electromigration. Barrier layers 144, 160, 170, 210, 220, 230, and 240 increase reliability for interconnect substrate or ETS 182a by reducing or inhibiting electromigration between internal conductive layers 138, 164, 214, and 234. In a similar manner, barrier layers 146, 162, 172, 212, 222, 232, and 242 inhibit electromigration with respect to conductive layers 140, 166, 216, and 236 to increase reliability for interconnect substrate or ETS 252b.

In FIG. 3k, electrical components 260a and 260b are disposed over interconnect substrate 182a and electrically and mechanically connected to conductive layer 138 of ETS 252a, similar to FIGS. 2p-2q. For example, electrical component 260a-260b can be similar to, or made similar to, semiconductor die 104 from FIG. 1c with bumps 114 oriented toward conductive layer 138. Electrical components 260a-260b can be other semiconductor die, semiconductor packages, surface mount devices, RF components, discrete electrical devices, or integrated passive devices (IPD).

An electrically conductive bump material is deposited into vias 247 over conductive layer 234 on interconnect substrate or ETS 252a using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 234 using a suitable attachment or bonding process. In one embodiment, the bump material is reflowed by heating the material above its melting point to form balls or bumps 264. In one embodiment, bump 264 is formed over a UBM having a wetting layer, barrier layer, and adhesive layer. Bump 264 can also be compression bonded or thermocompression bonded to conductive layer 234. Bump 264 represents one type of interconnect structure that can be formed over conductive layer 234. The interconnect structure can also use bond wires, conductive paste, stud bump, micro bump, or other electrical interconnect. The combination of interconnect substrate or ETS 252a and electrical components 260a-260b constitutes semiconductor package 270.

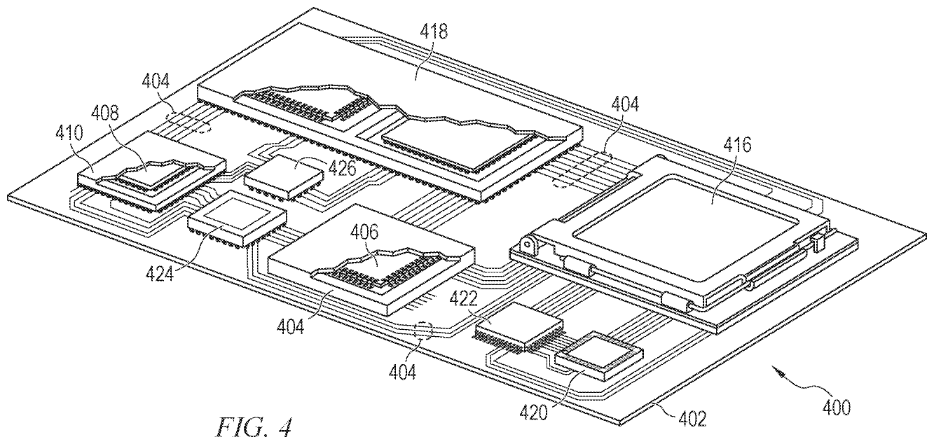

FIG. 4 illustrates electrical device 400 having a chip carrier substrate or PCB 402 with a plurality of semiconductor packages disposed on a surface of PCB 402, including semiconductor packages 194 and 270. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 4, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
an interconnect substrate including a first conductive layer and a first barrier layer formed over a first portion of the first conductive layer and a second barrier layer formed over a second portion of the first conductive layer; and
an electrical component disposed over the interconnect substrate.

2. The semiconductor device of claim 1, wherein the first barrier layer includes a conductive material and the second barrier layer includes a non-conductive material.

3. The semiconductor device of claim 1, wherein the first barrier layer includes a conductive material.

4. The semiconductor device of claim 1, wherein the second barrier layer includes a non-conductive material.

5. The semiconductor device of claim 1, wherein the interconnect structure further includes:
a second conductive layer coupled to the first conductive layer;
a third barrier layer formed over a first portion of the second conductive layer; and
a fourth barrier layer formed over a second portion of the second conductive layer.

6. The semiconductor device of claim 4, wherein the interconnect structure further includes an insulating layer formed between the first conductive layer and second conductive layer.

7. A semiconductor device, comprising:
an interconnect substrate including a first conductive layer and a first barrier layer formed over the first conductive layer; and
an electrical component disposed over the interconnect substrate.

8. The semiconductor device of claim 7, wherein the interconnect substrate further includes a second barrier layer formed over the first conductive layer.

9. The semiconductor device of claim 7, wherein the first barrier layer includes a conductive material and the second barrier layer includes a non-conductive material.

10. The semiconductor device of claim 8, wherein the first barrier layer includes a conductive material.

11. The semiconductor device of claim 7, wherein the second barrier layer includes a non-conductive material.

12. The semiconductor device of claim 7, wherein the interconnect structure further includes:
a second conductive layer coupled to the first conductive layer;
a third barrier layer formed over the second conductive layer; and
a fourth barrier layer formed over the second conductive layer.

13. The semiconductor device of claim 12, wherein the interconnect structure further includes an insulating layer formed between the first conductive layer and second conductive layer.

14. A method of making a semiconductor device, comprising:
providing an interconnect substrate including a first conductive layer and a first barrier layer formed over a first portion of the first conductive layer and a second barrier layer formed over a second portion of the first conductive layer; and
disposing an electrical component over the interconnect substrate.

15. The method of claim 14, wherein the first barrier layer includes a conductive material and the second barrier layer includes a non-conductive material.

16. The method of claim 14, wherein the first barrier layer includes a conductive material.

17. The method of claim 14, wherein the second barrier layer includes a non-conductive material.

18. The method of claim 14, wherein providing the interconnect structure further includes:
providing a second conductive layer coupled to the first conductive layer;
forming a third barrier layer over a first portion of the second conductive layer; and
forming a fourth barrier layer over a second portion of the second conductive layer.

19. The method of claim 17, wherein providing the interconnect structure further includes forming an insulating layer between the first conductive layer and second conductive layer.

20. A method of making a semiconductor device, comprising:
providing an interconnect substrate including a first conductive layer and a first barrier layer formed over the first conductive layer; and
disposing an electrical component over the interconnect substrate.

21. The method of claim 20, wherein providing the interconnect substrate further includes forming a second barrier layer over the first conductive layer.

22. The method of claim 21, wherein the second barrier layer includes a non-conductive material.

23. The method of claim 20, wherein the first barrier layer includes a conductive material.

24. The method of claim 20, wherein providing the interconnect structure further includes:
providing a second conductive layer coupled to the first conductive layer;
forming a third barrier layer over the second conductive layer; and
forming a fourth barrier layer over the second conductive layer.

25. The method of claim 24, wherein providing the interconnect structure further includes forming an insulating layer between the first conductive layer and second conductive layer.
